(19) United States
(12) Patent Application Publication
(10) Pub. No.: US 2024/0310683 A1
(43) Pub. Date: Sep. 19, 2024

(54) DISPLAY PANELS

(71) Applicant: TCL CHINA STAR OPTOELECTRONICS TECHNOLOGY CO., LTD., Shenzhen (CN)

(72) Inventor: Dongming SU, Shenzhen (CN)

(73) Assignee: TCL CHINA STAR OPTOELECTRONICS TECHNOLOGY CO., LTD., Shenzhen (CN)

(21) Appl. No.: 18/324,981

(22) Filed: May 28, 2023

(30) Foreign Application Priority Data
Dec. 30, 2022 (CN) 202211729590.2
Mar. 17, 2023 (CN) 202310291094.1

(51) Int. Cl. G02F 1/1362; G02F 1/1343; H01L 27/12

(52) U.S. Cl. CPC G02F 1/136213; G02F 1/134345; H01L 27/1255; G02F 1/13439; G02F 1/1368; G02F 2201/123; G02F 2201/52; G02F 2202/10

(57) ABSTRACT

A display panel is provided. The display panel includes a substrate and a plurality of subpixels arranged on the substrate at intervals. Each of the subpixels includes a control area and a pixel area. The display panel in the pixel area includes a storage capacitor disposed on the substrate, a pixel electrode disposed on a side of the storage capacitor away from the substrate, and an isolation layer disposed between the storage capacitor and the pixel electrode. In the pixel area, the storage capacitor is provided with a through hole, and a projection of the through hole on the substrate at least partially overlaps with a projection of the pixel electrode on the substrate.

### CROSS-REFERENCE TO RELATED APPLICATION

This application claims priority to Chinese Patent Application No. 202310291094.1, filed on Mar. 17, 2023, the disclosure of which is incorporated herein by reference in its entirety.

### TECHNICAL FIELD

The present disclosure relates to the field of display technologies, and in particular, to display panels.

### BACKGROUND

A display device can convert the data of a computer into various characters, numbers, symbols, or intuitive images and display them, can use a keyboard and other input tools to input commands or data into the computer, and can add, delete, modify, and change the display content at any time with the help of hardware and software of the system of the computer. Display devices are classified into plasma, liquid crystal, light emitting diode, and cathode ray tube according to the display panels used.

The liquid crystal display device (LCD) uses a liquid crystal material filled between two parallel plates as a basic component, and an arrangement of molecules inside the liquid crystal material is changed through a voltage to achieve the purpose of light shielding and light transmission to display images of different shades and well-arranged patterns. As long as a filter layer of three primary colors is added between the two plates, the display of color images can be realized.

A transparent electrode layer needs to be added as a storage capacitor in the traditional transparent storage capacity and shielding layer (TSS) technologies. In order to isolate the storage capacitor and a pixel electrode, a thick isolation layer needs to be provided between the storage capacitor and the pixel electrode. In related art, a thickness of the isolation layer needs to be 2.2 μm to effectively isolate the storage capacitor and the pixel electrode. An insufficient thickness of the isolation layer may easily lead to a problem of dark spots.

In the related art, in order to achieve the isolation layer having the thickness of 2.2 μm, high exposure is required, which leads to complex processes and a high power consumption, thereby seriously restricting the operation of the factory.

### SUMMARY

In view of above, a display panel according to embodiments of the present disclosure is provided. The display panel includes a substrate and a plurality of subpixels arranged on the substrate at intervals. Each of the subpixels includes a control area and a pixel area. The display panel in the pixel area includes a storage capacitor disposed on the substrate, a pixel electrode disposed on a side of the storage capacitor away from the substrate, and an isolation layer disposed between the storage capacitor and the pixel electrode. In the pixel area, the storage capacitor is provided with a through hole, and a projection of the through hole on the substrate at least partially overlaps with a projection of the pixel electrode on the substrate.

### BRIEF DESCRIPTION OF THE DRAWINGS

FIG. 1 is a plane view of a display panel according to an embodiment of the present disclosure.

FIG. 2 is a plane view of a pixel area of a subpixel according to embodiment 1 of the present disclosure.

FIG. 3 is a plane view of a pixel electrode according to an embodiment of the present disclosure.

FIG. 4 is a plane view of a storage capacitor according to embodiment 1 of the present disclosure.

FIG. 5 is a schematic structural view of a control area of the subpixel according to embodiment 1 of the present disclosure.

FIG. 6 is a plane view of a storage capacitor according to embodiment 2 of the present disclosure.

FIG. 7 is a plane view of a pixel area of a subpixel according to embodiment 3 of the present disclosure.

FIG. 8 is a plane view of a storage capacitor according to embodiment 3 of the present disclosure.

List of reference numerals in the drawings:
100, display panel; 1, substrate; 2, subpixel; 3, storage capacitor; 4, pixel electrode; 5, isolation layer; 6, thin film transistor device; 7, common electrode; 21, control area; 22, pixel area; 2201, first subpixel area; 2202, second subpixel area; 2203, third subpixel area; 2204, fourth subpixel area; 31, through hole; 311, first trunk; 312, second trunk; 313, first branch; 314, second branch; 315, third branch; 316, fourth branch; 41, first trunk electrode; 42, second trunk electrode; 43, first branch electrode; 44, second branch electrode; 45, third branch electrode; 46, fourth branch electrode; 61, gate; 62, gate insulating layer; 63, active layer; 64, source and drain layer; 641, source; 642, drain.

### DETAILED DESCRIPTION

Some embodiments of the present disclosure will be described below in detail with reference to the accompanying drawings, but not intended to limit the present disclosure.

In the illustration of the present disclosure, it should be understood that orientation and positional relationships indicated by the terms “center”, “longitudinal”, “transverse”, “length”, “width”, “thickness”, “upper”, “lower”, “front”, “back”, “left”, “right”, “vertical”, “horizontal”, “lateral”, “top”, “bottom”, “inner”, “outer”, “clockwise”, “counterclockwise”, etc. are based on the orientation or positional relationship shown in the drawings, which is only for the convenience of illustrating the present disclosure and simplifying the description, rather than indication or implies that the device or component must have a specific orientation to a specific orientation configuration and operation, and therefore should not be construed as limiting the present disclosure.

In addition, the terms, such as “first”, “second”, “third”, “fourth”, and so on, are only used for descriptive purposes and cannot be understood as indicating or implying relative importance or implicitly indicating the number of indicated technical features.

In the drawings, components with the same structure are denoted by the same numerals, and components with similar structures or functions are denoted by similar numerals. In addition, for ease of understanding and description, the size and thickness of each component shown in the drawings are arbitrarily shown, and the present disclosure does not limit the size and thickness of each component.

### Embodiment 1

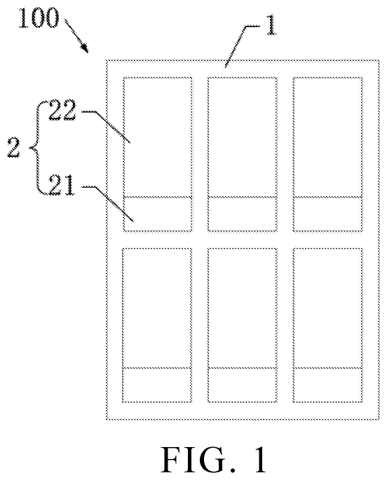

As shown in FIG. 1, the embodiment provides a display panel 100. The display panel 100 includes a substrate 1 and a plurality of subpixels 2 arranged on the substrate 1 at intervals.

A material of the substrate 1 is one or more of glass, polyimide, polycarbonate, polyethylene terephthalate, or polyethylene naphthalate. In this way, the substrate 1 has good impact resistance and can effectively protect the display panel 100.

The subpixel 2 includes a first subpixel, a second subpixel, and a third subpixel with different colors. The first subpixel, the second subpixel, and the third subpixel are respectively a red subpixel, a blue subpixel, and a green subpixel. In other embodiments, the subpixel 2 may further include subpixels with other colors.

As shown in FIG. 1, each subpixel 2 is provided with a control area 21 and a pixel area 22.

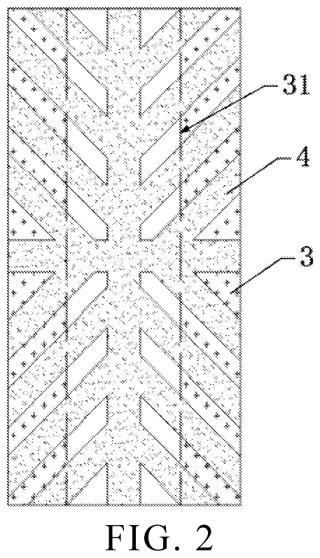

As shown in FIG. 2, in the pixel area 22, the display panel 100 includes a storage capacitor 3, a pixel electrode 4, and an isolation layer 5.

The storage capacitor 3 is disposed on the substrate 1. A material of the storage capacitor 3 is a light-transmitting material. The material of the storage capacitor 3 includes indium tin oxide (ITO). In the embodiment, the material of the storage capacitor 3 is ITO, which can improve light transmittance and brightness of the display panel 100.

The pixel electrode 4 is disposed on a side of the storage capacitor 3 away from the substrate 1. A material of the pixel electrode 4 is a light-transmitting material. The material of the pixel electrode 4 includes indium tin oxide (ITO). In the embodiment, the material of the pixel electrode 4 is ITO, which can improve light transmittance and brightness of the display panel 100.

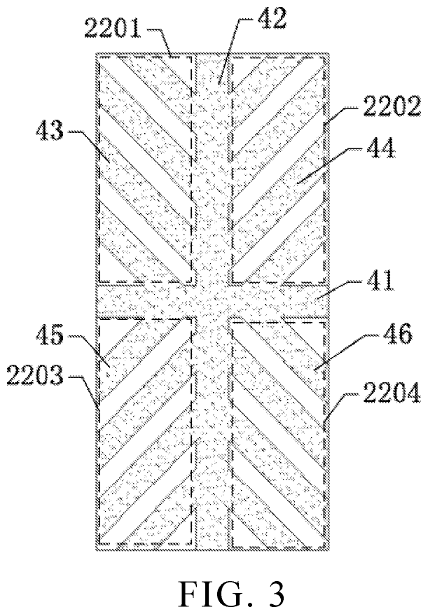

As shown in FIG. 2 and FIG. 3, the pixel electrode 4 includes a first trunk electrode 41 and a second trunk electrode 42 intersecting with each other. The first trunk electrode 41 and the second trunk electrode 42 divides the pixel area 22 into a first subpixel area 2201, a second subpixel area 2202, a third subpixel area 2203, and a fourth subpixel area 2204. In the embodiment, the first trunk electrode 41 and the second trunk electrode 42 are perpendicular to each other.

As shown in FIG. 2 and FIG. 3, the pixel electrode 4 further includes first branch electrodes 43, second branch electrodes 44, third branch electrodes 45, and fourth branch electrodes 46 disposed in the first subpixel area 2201, the second subpixel area 2202, the third subpixel area 2203, and the fourth subpixel area 2204, respectively.

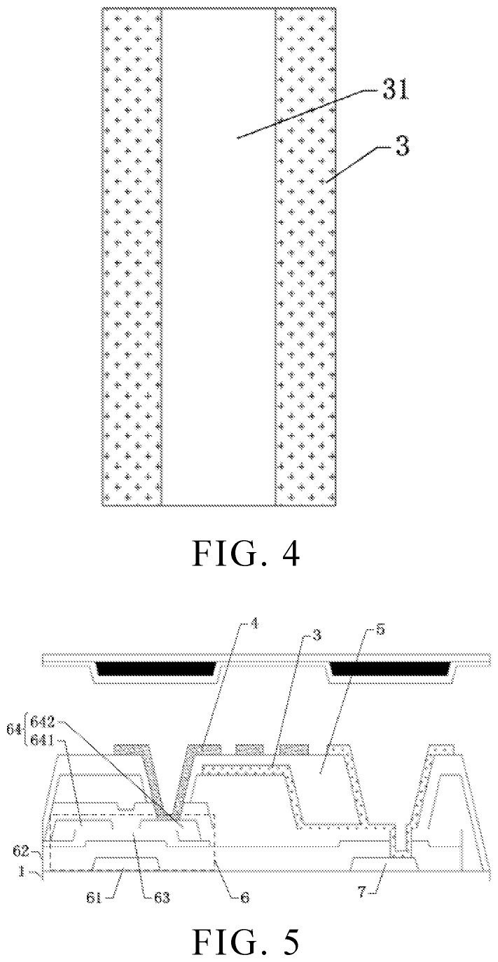

As shown in FIG. 2 and FIG. 4, in the pixel area 22, the storage capacitor 3 is provided with a through hole 31 thereon to reduce an overlapping area of a projection of the pixel electrode 4 on the substrate 1 and a projection of the storage capacitor 3 on the substrate 1, that is, a projection of the through hole 31 on the substrate 1 at least partially overlaps with the projection of the pixel electrode 4 on the substrate 1, so as to relieve the problem of dark spots, thereby avoiding the problem of complex processes and a high power consumption, which seriously restricts the operation of the factory, due to a high exposure required in preparation of the isolation layer having the thickness of 2.2 μm in the related art.

As shown in FIG. 4, a projection of the through hole 31 on the substrate 1 is shaped as a rectangle, a circle, or a triangle. In the embodiment, the projection of the through hole 31 on the substrate 1 is a rectangle.

As shown in FIG. 5, in the control area 21, the display panel 100 includes a thin film transistor device 6 and a common electrode 7.

The thin film transistor device 6 is disposed on the substrate 1. The thin film transistor device 6 includes a gate 61, a gate insulating layer 62, an active layer 63, and a source and drain layer 64.

The gate 61 is disposed on the substrate 1. The gate 61 corresponds to a channel of the active layer 63. A material of the gate 61 may be Mo, or a combination of Mo and Al, or a combination of Mo and Cu, or a combination of Mo, Cu, and IZO, or a combination of IZO, Cu, and IZO, or a combination of Mo, Cu, and ITO, or a combination of Ni, Cu, and Ni, or a combination of MoTiNi, Cu, and MoTiNi, or a combination of NiCr, Cu, and NiCr, or CuNb, etc.

The gate insulating layer 62 is disposed on a side of the gate 61 away from the substrate 1 and extends to cover the substrate 1. The gate insulating layer 62 is mainly configured to prevent short circuit arising from contact between the gate 61 and the active layer 63. A material of the gate insulating layer 62 may be SiOx, or SiNx, or Al₂O₃, or a combination of SiNx and SiOx, or a combination of SiOx, SiNx, and SiOx.

The active layer 63 is disposed on a side of the gate insulating layer 62 away from the substrate 1.

The source and drain layer 64 is disposed on a side of the active layer 63 away from the substrate 1. The source and drain layer 64 includes a source 641 and a drain 642 electrically connected to two ends of the active layer 63, respectively.

The pixel electrode 4 is electrically connected to the source and drain layer 64. Specifically, the pixel electrode 4 is electrically connected to the drain 642.

The common electrode 7 is disposed on the substrate 1 and in a same layer with the gate 61. Therefore, the common electrode 7 and the gate 61 can be prepared and formed in one process at the same time, which saves production costs. The storage capacitor 3 is electrically connected to the common electrode 7.

The isolation layer 5 is disposed between the storage capacitor 3 and the pixel electrode 4, and is mainly configured to prevent short circuit arising from contact between the storage capacitor 3 and the pixel electrode 4, which leads to the problem of dark spots. In the embodiment, a material of the isolation layer 5 is PFA. In the embodiment, a thickness of the isolation layer 5 is 1.3 μm.

As shown in table 1, in the normal group 1, the isolation layer 5 is thickened to 2.2 μm; in the normal group 2, the isolation layer 5 is not thickened, and the storage capacitor 3 is not provided with the through hole; in the embodiment 1, the isolation layer 5 is not thickened, but the storage capacitor 3 is provided with the through hole 31 thereon. Referring to the normal group 2 and the embodiment 1, it can be noted that, in the pixel area 22 of the embodiment, the storage capacitor 3 is provided with the through hole 31 thereon, when the overlapping area of the projection of the pixel electrode 4 on the substrate 1 and the projection of the storage capacitor 3 on the substrate 1 is reduced to a ratio of 50%, the dark spots may be expectedly reduced by about 40%, which can meet specifications about the dark spots of most products.

TABLE 1

| | Normal group | Normal group | Embodiment |
|---|---|---|---|
| | 1 | 2 | 1 |
| Thickness of the | 2.2 um | 1.3 um | 1.3 um |
| isolation layer | | | |
| Ratio of the overlapping | 100% | 100% | 50% |
| area of the storage | | | |
| capacitor and the pixel | | | |
| electrode | | | |
| Number of dark spots | 0.56/cm² | 5.43/cm² | 3.32/cm² |

### Embodiment 2

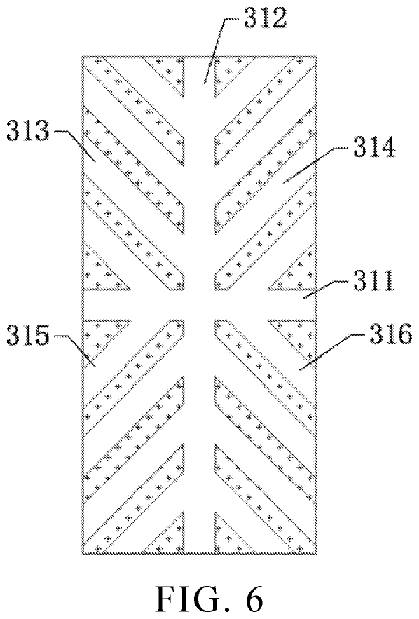

As shown in FIG. 6, the display panel in the embodiment has most of the technical features of the display panel in Embodiment 1, but has differences: in the embodiment, a profile of the through hole 31 includes a profile of a first trunk 311 and a second trunk 312 intersecting with each other, and includes a profile of first branches 313, second branches 314, third branches 315, and fourth branches 316 disposed in the first subpixel area 2201, the second subpixel area 2202, the third subpixel area 2203, and the fourth subpixel area 2204, respectively.

A projection of the first trunk electrode 41, a projection of the second trunk electrode 42, a projection of the first branch electrode 43, a projection of the second branch electrode 44, a projection of the third branch electrode 45, and a projection of the fourth branch electrode 46 on the substrate 1 fall within a projection of the first trunk 311, a projection of the second trunk 312, a projection of the first branch 313, a projection of the second branch 314, a projection of the third branch 315, and a projection of the fourth branch 316 on the substrate 1, respectively.

As shown in FIG. 6, in the embodiment, the projection of the first trunk electrode 41, the projection of the second trunk electrode 42, the projection of the first branch electrode 43, the projection of the second branch electrode 44, the projection of the third branch electrode 45, and the projection of the fourth branch electrode 46 on the substrate 1 are completely overlapped with the projection of the first trunk 311, the projection of the second trunk 312, the projection of the first branch 313, the projection of the second branch 314, the projection of the third branch 315, and the projection of the fourth branch 316 on the substrate 1, respectively.

In other embodiments, a width of the first trunk 311, a width of the second trunk 312, a width of the first branch 313, a width of the second branch 314, a width of the third branch 315, and a width of the fourth branch 316 may be greater than a width of the first trunk electrode 41, a width of the second trunk electrode 42, a width of the first branch electrode 43, a width of the second branch electrode 44, a width of the third branch electrode 45, and a width of the fourth branch electrode 46, respectively, so as to avoid a display problem of Mura of the display panel 100 caused by difference in the overlapping area caused by alignment of different film layers or expansion and contraction of the glass.

In the simulation, compared with the display panel in Embodiment 1, the display panel in the embodiment can achieve a same storage capacitance goal through less overlapping area, which is more conducive to relieve the dark spots and lower consumption of the isolation layer.

In the display panel in the embodiment, the storage capacitor 3 in the pixel area 22 is provided with the through hole 31 thereon, which is configured to reduce the overlapping area of the projection of the pixel electrode 4 on the substrate 1 and the projection of the storage capacitor 3 on the substrate 1, so that the problem of dark spots is relieved, thereby avoiding the problem of complex processes and a high power consumption, which seriously restricts the operation of the factory, due to a high exposure required in preparation of the isolation layer having the thickness of 2.2 μm in the related art.

### Embodiment 3

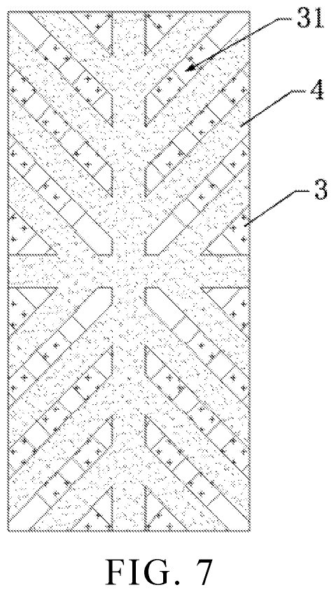

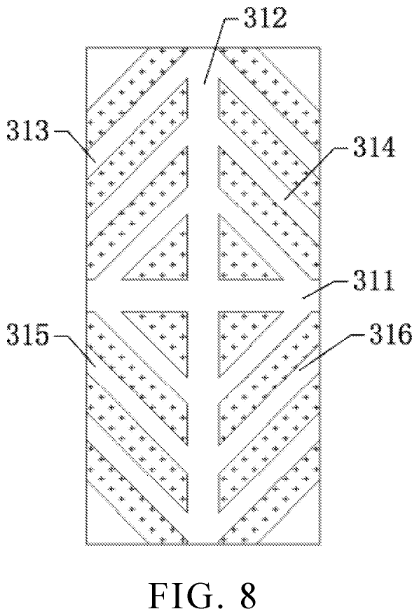

As shown in FIG. 7 and FIG. 8, the display panel in the embodiment has most of the technical features of the display panel in Embodiment 2, but has differences: in the embodiment, the projection of the first branch electrode 43, the projection of the second branch electrode 44, the projection of the third branch electrode 45, and the projection of the fourth branch electrode 46 on the substrate 1 are intersected with the projection of the first branch 313, the projection of the second branch 314, the projection of the third branch 315, and the projection of the fourth branch 316 on the substrate 1, respectively.

In the embodiment, the projection of the first branch electrode 43, the projection of the second branch electrode 44, the projection of the third branch electrode 45, and the projection of the fourth branch electrode 46 on the substrate 1 are perpendicular to the projection of the first branch 313, the projection of the second branch 314, the projection of the third branch 315, and the projection of the fourth branch 316 on the substrate 1, respectively. Therefore, there will be no difference in the overlapping area caused by alignment of different film layers or expansion and contraction of the glass, and thus no display problem of Mura of the display panel 100 will be occurred.

Specifically, the width of the first branch electrode 43, the width of the second branch electrode 44, the width of the third branch electrode 45, and the width of the fourth branch electrode 46 are equal to the width of the first branch 313, the width of the second branch 314, the width of the third branch 315, and the width of the fourth branch 316, respectively.

In the simulation, compared with the display panel in Embodiment 1, the display panel in the embodiment can achieve a same storage capacitance goal through less overlapping area, which is more conducive to relieve the dark spots and lower consumption of the isolation layer.

In the display panel in the embodiment, the storage capacitor 3 in the pixel area 22 is provided with the through hole 31 thereon, which is configured to reduce the overlapping area of the projection of the pixel electrode 4 on the substrate 1 and the projection of the storage capacitor 3 on the substrate 1, so that the problem of dark spots is relieved, thereby avoiding the problem of complex processes and a high power consumption, which seriously restricts the operation of the factory, due to a high exposure required in preparation of the isolation layer having the thickness of 2.2 μm in the related art.

The display panels according to embodiments of the present disclosure have been described above in detail. In this paper, specific examples are used to illustrate the principle and implementation of the invention. The description of the above embodiments is only used to help understand the method of the present disclosure and its core idea. Those skilled in the art can make various changes and modifications without departing from the spirit of the present disclosure. Therefore, the described embodiments are not intended to limit the present disclosure.

What is claimed is:

1. A display panel, comprising a substrate and a plurality of subpixels arranged on the substrate at intervals, each of the subpixels comprising a control area and a pixel area, and the display panel in the pixel area comprising:
a storage capacitor disposed on the substrate;
a pixel electrode disposed on a side of the storage capacitor away from the substrate; and
an isolation layer disposed between the storage capacitor and the pixel electrode,
wherein in the pixel area, the storage capacitor is provided with a through hole, and a projection of the through hole on the substrate at least partially overlaps with a projection of the pixel electrode on the substrate.

2. The display panel according to claim 1, wherein a projection of the through hole on the substrate is shaped as a rectangle, a circle, or a triangle.

3. The display panel according to claim 1, wherein the pixel electrode comprises:
a first trunk electrode;
a second trunk electrode intersecting with the first trunk electrode, wherein the first trunk electrode and the second trunk electrode divides the pixel area into a first subpixel area, a second subpixel area, a third subpixel area, and a fourth subpixel area; and
first branch electrodes, second branch electrodes, third branch electrodes, and fourth branch electrodes disposed in the first subpixel area, the second subpixel area, the third subpixel area, and the fourth subpixel area, respectively;
wherein a profile of the through hole comprises a profile of a first trunk and a second trunk intersecting with each other, and comprises a profile of first branches, second branches, third branches, and fourth branches disposed in the first subpixel area, the second subpixel area, the third subpixel area, and the fourth subpixel area, respectively.

4. The display panel according to claim 3, wherein a projection of the first trunk electrode, a projection of the second trunk electrode, a projection of each of the first branch electrodes, a projection of each of the second branch electrodes, a projection of each of the third branch electrodes, and a projection of each of the fourth branch electrodes on the substrate fall within a projection of the first trunk, a projection of the second trunk, a projection of one of the first branches, a projection of one of the second branches, a projection of one of the third branches, and a projection of one of the fourth branches on the substrate, respectively.

5. The display panel according to claim 4, wherein the projection of the first trunk electrode, the projection of the second trunk electrode, the projection of each of the first branch electrodes, the projection of each of the second branch electrodes, the projection of each of the third branch electrodes, and the projection of each of the fourth branch electrodes on the substrate are completely overlapped with the projection of the first trunk, the projection of the second trunk, the projection of one of the first branches, the projection of one of the second branches, the projection of one of the third branches, and the projection of one of the fourth branches on the substrate, respectively.

6. The display panel according to claim 3, wherein a projection of the first trunk electrode, a projection of the second trunk electrode, a projection of each of the first branch electrodes, a projection of each of the second branch electrodes, a projection of each of the third branch electrodes, and a projection of each of the fourth branch electrodes on the substrate are intersected with a projection of the first trunk, a projection of the second trunk, a projection of one of the first branches, a projection of one of the second branches, a projection of one of the third branches, and a projection of one of the fourth branches on the substrate, respectively.

7. The display panel according to claim 6, wherein the projection of the first trunk electrode, the projection of the second trunk electrode, the projection of each of the first branch electrodes, the projection of each of the second branch electrodes, the projection of each of the third branch electrodes, and the projection of each of the fourth branch electrodes on the substrate are perpendicular to the projection of the first trunk, the projection of the second trunk, the projection of one of the first branches, the projection of one of the second branches, the projection of one of the third branches, and the projection of one of the fourth branches on the substrate, respectively.

8. The display panel according to claim 1, wherein a material of the storage capacitor and the pixel electrode is a light-transmitting material.

9. The display panel according to claim 8, wherein the material of the storage capacitor and the pixel electrode comprises indium tin oxide.

10. The display panel according to claim 1, wherein the display panel in the control area comprises:
a thin film transistor device, disposed on the substrate and comprising a gate, a gate insulating layer, an active layer, and a source and drain layer; and
a common electrode, disposed on the substrate and in a same layer with the gate; and
wherein the pixel electrode is electrically connected to the source and drain layer, and the storage capacitor is electrically connected to the common electrode.

11. The display panel according to claim 1, wherein each of the subpixels comprises a first subpixel, a second subpixel, and a third subpixel with different colors, and the first subpixel, the second subpixel, and the third subpixel are a red subpixel, a blue subpixel, and a green subpixel, respectively.
